(19) United States
(12) Patent Application Publication
(10) Pub. No.: US 2004/0129559 A1
(43) Pub. Date: Jul. 8, 2004

(54) Diffusion bonded assemblies and fabrication methods

(76) Inventor: Josh W. Misner, Spokane, WA (US)

Correspondence Address: Honeywell International Inc, P O Box 2245, 101 Columbia Road, Morristown, NJ, 07962, US

(21) Appl. No.: 10/475,251

(22) PCT Filed: Apr. 12, 2002
(86) PCT No.: PCT/US02/11686

(51) Int. Cl. C23C 14/32; B23K 28/00

(52) U.S. Cl. 204/298.12; 228/193; 204/298.13

(57) ABSTRACT

A diffusion bonded PVD target assembly (30) includes a target blank (34) bonded directly to a backing plate (32), a majority crystal structure of the target blank comprising a HCP structure. The target blank can include cobalt and the backing plate can include an aluminum or copper alloy. The target assembly can exhibit a thickness dependent high PTF, such as at least about 60%. A PVD target fabrication method includes diffusion bonding a target blank to a backing plate, a majority crystal structure of the target blank comprising a HCP structure; transitioning at least some of the HCP structure to a non-HCP structure; and restoring a majority of the non-HCP structure to the HCP structure. The transitioning can include hot pressing the target blank and backing plate at a temperature exceeding a HCP to non-HCP transition temperature of the target blank. The restoring can include cooling at a specified low rate.

### TECHNICAL FIELD

The present application pertains to diffusion bonded PVD target assemblies and fabrication methods.

### BACKGROUND OF THE INVENTION

Physical vapor deposition (PVD) targets are commonly used in a variety of industries to deposit thin films of materials. Sputtering is the most prevalent example of PVD. High purity cobalt targets have become particularly significant in PVD applications to produce thin films on microelectronic devices such as microprocessors, memory, etc. A cobalt sputtering target blank is typically solder bonded to a copper backing plate using indium or tin as an interlayer. However, the sputtering generally occurs at less than 4 kilowatts of power. If more power is applied, a significant risk of melting the solder exists that would possibly debond the target from the backing plate inside a sputtering chamber.

Diffusion bonding of a cobalt target blank or a target blank of another material can be performed instead of solder bonding. In the case of cobalt targets specifically, as well as potentially other target materials, the temperatures typically used for diffusion bonding can produce an undesirable change in a crystal structure of a target blank. Cobalt is ferromagnetic and can resist magnetic field penetration during sputtering. Accordingly, methods have been developed to reduce the anisotropic nature of the magnetic properties for cobalt to provide an improved pass through flux (PTF). As a low flux material, cobalt sputtering targets are typically somewhat thin which results in relatively short service life. Further, low PTF can bring about premature development of a highly localized erosion trench in a sputtering target that reduces target life, resulting in poor utilization of the remaining target material.

Methods have been developed to produce a PVD target blank wherein a majority crystal structure of the target blank includes a hexagonal closest packing (HCP) structure rather than a face center cubic (FCC) structure. PTF can be improved by producing cobalt targets with a majority HCP structure. Previously, attempts to diffusion bond a cobalt target blank to a backing plate results in a transition of the HCP structure to an FCC structure at a transition temperature of about 412° C. Lower temperatures are typically not as effective for diffusion bonding directly to a backing plate. The transition to a FCC structure significantly reduces the PTF of a PVD target thereby reducing sputtering performance and overall life of the target.

As described above, presently a choice exists whether to produce a high PTF, solder bonded target that is operated at low power or a low PTF diffusion bonded target that can be operated at higher power. Instead, a need exists for diffusion bonded targets that exhibit a high PTF and methods for producing such devices. A cobalt target diffusion bonded to a backing plate may operate at greater than 4 kilowatts of power, allowing higher rates of deposition. Retaining the high PTF characteristics of the HCP structure in addition to diffusion bonding may offer higher rates of deposition as well as an extended target life, using more of the target material and reducing the cost of production.

### SUMMARY OF THE INVENTION

According to one aspect of the invention, a diffusion bonded PVD target assembly includes a target blank bonded directly to a backing plate, a majority crystal structure of the target blank comprising a HCP structure. As an example, the target blank can consist essentially of cobalt or a cobalt alloy with cobalt as the predominate metal. The backing plate can consist essentially of aluminum, an aluminum alloy with aluminum as the predominate metal, copper, or a copper alloy with copper as the predominate metal. The target assembly can exhibit a high PTF, preferably at least about 60%.

In another aspect of the invention, a diffusion bonded PVD target assembly includes a target blank bonded to a backing plate, the target blank comprising a target surface, a majority crystal structure of the target blank comprising a HCP structure, and a majority crystallographic orientation of the target blank comprising a {002} HCP plane that is substantially parallel to the target surface within a test region.

In a further aspect of the invention, a PVD target fabrication method includes diffusion bonding a target blank to a backing plate and forming a target assembly, a majority crystal structure of the target blank comprising a HCP structure; transitioning at least some of the HCP structure to a non-HCP structure; and restoring a majority of the non-HCP structure to the HCP structure. As an example, the transitioning can include hot pressing the target blank and backing plate during the diffusion bonding at a temperature exceeding a HCP to non-HCP transition temperature of the target blank. The non-HCP structure can be a FCC structure. Also, the target blank can exhibit a high PTF both before the diffusion bonding and after the restoring.

In a still further aspect of the invention, a PVD target fabrication method includes diffusion bonding a target blank to a backing plate at a bonding temperature and forming a target assembly; and cooling the target blank from the bonding temperature to a room temperature of from about 10° C. to about 30° C. at a rate sufficient that PTF of the diffusion bonded target blank changes by greater than −10% in comparison to the target blank PTF before the diffusion bonding. As an example, the cooling rate can be less than or equal to about 5° C. per minute.

### BRIEF DESCRIPTION OF THE DRAWINGS

Preferred embodiments of the invention are described below with reference to the following accompanying drawings.

FIG. 1 shows a sectional view of a target/backing plate construction with a target formed in accordance with methodology of the present invention. The construction corresponds to a large ENDURA™ configuration.

FIG. 2 is a top view of the target/backing plate construction of FIG. 4.

### DETAILED DESCRIPTION OF THE PREFERRED EMBODIMENTS

According to one aspect of the invention, a PVD target fabrication method includes diffusion bonding a target blank to a backing plate and forming a target assembly, a majority crystal structure of the target blank including a HCP structure. The method includes transitioning at least some of the HCP structure to a non-HCP structure and then restoring a majority of the non-HCP structure back to the HCP structure. Any target blank known to those skilled in the art may be used for the target blank having a HCP structure as a majority crystal structure. One example of such a target blank and a method for producing the same is describe in U.S. patent application Ser. No. 09/139,240 filed Aug. 25, 1998 and titled “High Purity Cobalt Sputter Target and Process of Manufacturing Same”.

The transitioning of the HCP structure can include hot pressing the target blank and backing plate during the diffusion bonding at a temperature exceeding a HCP to non-HCP transition temperature of the target blank. In one example, the non-HCP structure can include a FCC structure. For cobalt, the HCP to FCC transition temperature is about 412° C. However, a different transition temperature may apply for other materials. Any diffusion bonding process known to those skilled in the art or later developed can be used to accomplish the diffusion bonding portion.

Preferably, the target blank exhibits a high PTF both before the diffusion bonding and after the restoring. PTF can be measured using conventional apparatuses that place a material in a magnetic field and measure the resulting flux passing through the material. PTF is measured in the Z-direction, which is normal to the target surface. PTF is expressed in percent and is equal to the mean magnetic field magnitude, in Gauss, detected passing through the target in a test region divided by the mean magnitude of the magnetic source in the test region, in Gauss. For example, a non-magnetic, non-ferromagnetic material such as aluminum generally exhibits a PTF of about 100%. One example of measuring PTF is described in U.S. patent application Ser. No. 09/631,856 filed Aug. 3, 2000 and titled “Method and Apparatus for Determining the Pass Through Flux of Magnetic Materials”.

As used in the context of the present application, the term “high PTF” is defined in relation to material thickness. For a PVD target blank, the minimum PTF for a high PTF material is determined using the formula 85-(100 x h), where h is target thickness measured in inches. For example, the minimum PTF for a 0.25 inch (0.64 centimeter) target to be considered high PTF is 60%. Comparably, the minimum PTF for a 0.1 inch (0.25 centimeter) target to be considered high PTF is 75%. PVD targets most frequently have a thickness of about 0.1 inch to about 0.25 inch, accordingly, a PVD target blank preferably exhibits a PTF of at least about 60%.

Observation indicates that high PTF can be found in target blanks with a majority crystallographic orientation comprising a {002} HCP plane that is substantially parallel to the target surface within a test region. Orientation can be measured using x-ray diffraction techniques known to those skilled in the art or any other available methods. As an example, the test region can define a representative test region. Establishing a majority orientation within a representative test region will tend to indicate the majority orientation is present throughout the target blank. Accordingly, the target surface can be a sputtering surface of the target assembly and the {002} HCP plane can be substantially parallel to the sputtering surface across the entirety of the sputtering surface. In the context of the present application, “substantially parallel” is defined to include a {002} HCP plane that might not be precisely parallel to the target surface, but such is the most probable orientation within the detection limits of the measurement technique.

As indicated, the method includes restoring a majority of the non-HCP structure to the HCP structure. Such restoring can include cooling the target blank from a diffusion bonding temperature to a room temperature of from about 10° C. to about 30° C. at a rate sufficient that the PTF after the cooling changes by greater than −10% in comparison to the PTF before the diffusion bonding. As one example, the PTF can change by about 0%. For a cobalt target blank, a cooling rate of less than or equal to about 5° C. per minute has been observed to restore a majority of the HCP structure that was present prior to conducting diffusion bonding.

Observation has further indicated that an improvement in PTF can be achieved using the aspects of the invention. Improvements of about 10% have been observed. It is not clear exactly why PTF at times increases after diffusion bonding and restoring an intermediate structure (for example, FCC) back to a final crystal structure (for example, HCP), but some possibilities exist. Possible explanations include the addition of stress built up during the diffusion bonding process and the advent of recrystallization occurring at particular pressures.

The diffusion bonding temperature can be greater than 412° C., the transition temperature of cobalt. Preferably, the diffusion bonding temperature is at least about 500° C. For cobalt, diffusion bonding temperature could be about 550° C. In keeping with the aspects of the invention described herein, similar preferred diffusion bonding temperatures and cooling rates can be established for target blanks composed of materials other than cobalt. Even so, the target blank preferably consists essentially of cobalt or a cobalt alloy with cobalt as the predominate metal. The target blank most preferably consists of cobalt. Also, the backing plate preferably consists essentially of aluminum, an aluminum alloy with aluminum as the predominate metal, copper, or a copper alloy with copper as the predominate metal.

Further, the diffusion bond can exhibit a bond strength of greater than 11 kilopounds per square inch (ksi) (76 megaPascals (MPa)). More preferably, the bond strength is greater than about 14 ksi (97 MPa) and most preferably greater than about 20 ksi (138 MPa).

In another aspect of the invention, a PVD target fabrication method includes diffusion bonding a target blank to a backing plate at a bonding temperature and forming a target assembly. The method includes cooling the target blank from the bonding temperature to a room temperature of from about 10° C. to about 30° C. at a rate sufficient that PTF of the diffusion bonded target blank changes by greater than −10% in comparison to the target blank PTF before the diffusion bonding. Preferably, the target blank exhibits a high PTF both before the diffusion bonding and after the cooling.

In a further aspect of the invention, a PVD target fabrication method includes diffusion bonding a cobalt-comprising target blank to an aluminum-comprising backing plate at a bonding temperature greater than 412° C. and forming a target assembly, the target blank exhibiting a PTF of at least about 60% before the diffusion bonding. The method includes cooling the target blank from the bonding temperature to a room temperature of from about 10° C. to about 30° C. at a rate of no more than about 5° C. per minute, the diffusion bonded target assembly exhibiting a PTF of at least about 60% after the cooling. The target blank can include a target surface, a majority crystal structure of the target blank can include a HCP structure, and a majority crystallographic orientation of the target blank can include a {002} HCP plane that is substantially parallel to the target surface within a test region.

The aspects of the present invention also include the various PVD target assemblies produced by the methods described herein. Additionally, one aspect of the invention includes a diffusion bonded PVD target assembly having a target blank bonded directly to a backing plate, a majority crystal structure of the target blank comprising a HCP structure. The target blank can include a magnetic material. Cobalt is one example of a magnetic material and is also ferromagnetic.

The target assembly can lack an interlayer between the target blank and the backing plate. Commonly, interlayers have been used between a sputtering target blank and a backing plate to enhance bond strength from diffusion bonding. Notably, adequate bond strength can be achieved in the various aspects of the present invention without use of an interlayer. However, use of an interlayer as known to those skilled in the art might still be used in some aspects of the present invention.

In the context of the present document, a target blank is diffusion bonded “directly to” a backing plate when it does not take advantage of any bond strength enhancements potentially afforded by an interlayer. Bond strength enhancements can be provided by an interlayer having a composition different from both the target blank and the backing plate. For example, a cobalt target diffusion bonded to an aluminum, aluminum alloy, copper, or copper alloy backing plate can include a bond enhancing interlayer containing silver, gold, palladium, platinum, and their alloys. However, a target blank diffusion bonded “directly to” a backing plate does not take advantage of such bond enhancing interlayers having compositions different from both the target blank and the backing plate.

Accordingly, diffusion bonding “directly to” a backing plate includes using interlayers that do not afford bond strength enhancements. For example, while not preferred, it is conceivable that a backing plate might be a multilayer structure, such as multiple aluminum or aluminum alloy layers combined together. A target blank diffusion bonded to such a multilayer backing plate is still considered as bonded directly to the backing plate despite the presence of a backing plate layer between the target blank and the remainder of the backing plate. The target assembly may be further specified as lacking any interlayer between the target blank and the backing plate to indicate a single layer target blank bonded directly to a single layer backing plate.

In another aspect of the invention, a diffusion bonded PVD target assembly includes a target blank bonded directly to a backing plate, the target blank consisting essentially of cobalt or a cobalt alloy, with cobalt as the predominant metal and exhibiting a high PTF. As described above, the term “high PTF” is defined relative to the thickness of magnetic material. The PVD target assembly can exhibit a PTF of at least about 60%. The backing plate can consist essentially of aluminum, an aluminum alloy with aluminum as the predominant metal, copper, or a copper alloy with copper as the predominant metal.

In a further aspect of the invention, a diffusion bonded PVD target assembly includes a target blank bonded to a backing plate, the target blank including a target surface and a magnetic material, a majority crystal structure of the target blank including a HCP structure, and a majority crystallographic orientation of the target blank including a {002} HCP plane that is substantially parallel to the target surface within a test region. As an option, the target blank can be bonded directly to a backing plate. Further, the PVD target assembly can exhibit a high PTF.

The methods described herein for fabricating a PVD target assembly can further include measures known to those skilled in the art as beneficial in the context of diffusion bonding. For example, scrolling of the target blank can be performed prior to diffusion bonding. For a target blank too thin to accommodate standard scrolling, grit blasting can be used to roughen the surface of the target blank prior to diffusion bonding.

Aluminum comprises a preferred backing plate material due to the low cost of materials and its light weight. However, it is conceivable that backing plates of other materials can be used in the various aspects of the invention. Higher or lower diffusion bonding temperatures might be used with backing plates of other materials. For example, a diffusion bonding temperature greater than 550° C. could be used for a copper backing plate. It is further conceivable that a majority of a non-HCP structure can still be restored back to the original HCP structure even though diffusion bonding occurs at temperatures greater than 550° C. Additionally, target blanks other than those consisting of cobalt can be used. Specifically, cobalt alloys, including without limitation silicon and/or titanium, may be suitable. Other combinations of target blank and backing plate materials may benefit from the principles of the various aspects of the invention described herein.

Due to the detrimental impact of diffusion bonding on PTF conventionally found in diffusion bonded targets, it is particularly advantageous that the methods described herein provide a diffusion bond while maintaining a majority HCP structure or a high PTF or both. It is particularly unexpected that adequate diffusion bonding can be achieved without an interlayer.

### EXAMPLE

The surface of a cobalt target blank having a high PTF was roughened by grit blasting to a roughness greater than 250 RA. The blank had a purity of at least 99.95 weight percent Co and an average grain size of less than about 100 microns. The blank was etched in a solution of dilute (less than 5%) sulfuric acid before being mated to a 6061-T4 aluminum backing plate. The assembly was placed in a hot isostatic press (or a vacuum hot press) and the temperature was ramped up to about 500° C. at a rate of about 600° C. per hour. Since the transition temperature of 412° C. was exceeded, the crystal structure transitioned from HCP to FCC. As an alternative, the temperature could be ramped to as high as 550° C. with suitable temperature controls when using an aluminum backing plate. A pressure of 4000 psi (28 MPa) was applied and the assembly held at the bonding temperature and pressure for a diffusion soak time of approximately 4 hours. After the diffusion soak time, the pressure was released and the temperature slowly cooled at a rate of no more than about 5° C. per minute to allow for transition of the FCC formed during diffusion bonding back to HCP. Variation of the processing conditions described, particularly pressure, is conceivable while still achieving the advantages described herein for the various aspects of the invention.

The described example was repeated for several cobalt targets and aluminum backing plates to produce the bond strength data shown in Table 1 without significantly changing the original PTF of the cobalt target blank. The described example was also used to diffusion bond cobalt target blanks to copper/chromium alloy target blanks producing the bond strength data in Table 1.

TABLE 1

| Materials | Bond Strength (psi) | Bond Strength (MPa) |
|---|---|---|
| Co blank/Al plate | 12182 | 84 |
| Co blank/Al plate | 12955 | 89 |
| Co blank/Al plate | 15477 | 107 |
| Co blank/Al plate | 11009 | 76 |
| Co blank/Al plate | 11268 | 78 |
| Co blank/Al plate | 17456 | 120 |
| Co blank/Al plate | 15329 | 106 |
| Co blank/Al plate | 18020 | 124 |
| Co blank/Al plate | 14587 | 101 |
| Co blank/Al plate | 15091 | 104 |
| Co blank/Al plate | 11973 | 82 |
| Co blank/Al plate | 14842 | 102 |
| Co blank/CuCr plate | 19383 | 134 |
| Co blank/CuCr plate | 15868 | 109 |
| Co blank/CuCr plate | 22508 | 155 |
| Co blank/CuCr plate | 19581 | 135 |

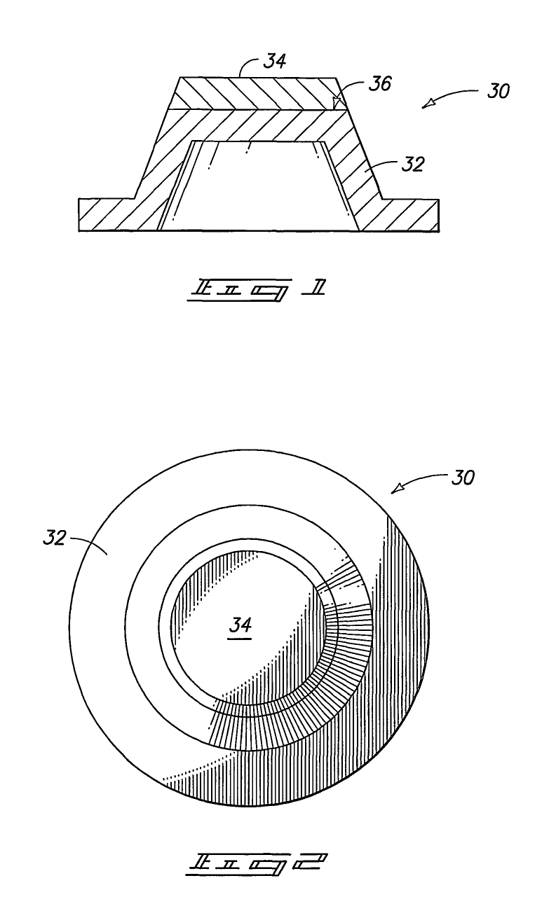

An exemplary backing plate/target assembly encompassed by the present invention is shown in FIGS. 1 and 2 as assembly 30. Assembly 30 comprises a backing plate 32 bonded to a target blank 34. Backing plate 32 and target blank 34 join at an interface 56, which can comprise, for example, a diffusion bond between the backing plate and target blank. Target blank 34 can comprise, for example, a cobalt target blank. Backing plate 32 and target blank 34 can comprise any of numerous configurations, with the shown configuration being exemplary. Backing plate 32 and target 34 can comprise, for example, an ENDURA™ configuration, and accordingly can comprise a round outer periphery. FIG. 5 shows assembly 30 in a top-view, and illustrates the exemplary round outer periphery configuration.

The invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted.

I claim:

1. A diffusion bonded PVD target assembly comprising a target blank bonded directly to a backing plate, a majority crystal structure of the target blank comprising a HCP structure and the target blank comprising a magnetic material.

2. The target assembly of claim 1 wherein the target assembly lacks an interlayer between the target blank and the backing plate.

3. The target assembly of claim 1 wherein the target blank consists essentially of cobalt or a cobalt alloy with cobalt as the predominate metal.

4. The target assembly of claim 1 wherein the backing plate consists essentially of aluminum, an aluminum alloy with aluminum as the predominate metal, copper, or a copper alloy with copper as the predominate metal.

5. The target assembly of claim 1 exhibiting a high PTF.

6. The target assembly of claim 1 exhibiting a PTF of at least about 60%.

7. The target assembly of claim 1 wherein the diffusion bond exhibits a bond strength of greater than about 11 ksi (76 MPa).

8. The target assembly of claim 1 wherein the target assembly comprises a sputtering target assembly.

9. A diffusion bonded PVD target assembly comprising a target blank bonded directly to a backing plate, the target blank consisting essentially of cobalt or a cobalt alloy, with cobalt as the predominate metal, and exhibiting a high PTF.

10. The target assembly of claim 9 wherein the target assembly lacks an interlayer between the target blank and the backing plate.

11. The target assembly of claim 9 wherein the target blank consists of cobalt.

12. The target assembly of claim 9 wherein the backing plate consists essentially of aluminum, an aluminum alloy with aluminum as the predominate metal, copper, or a copper alloy with copper as the predominate metal.

13. The target assembly of claim 9 exhibiting a PTF of at least about 60%.

14. The target assembly of claim 9 wherein the target blank comprises a target surface, a majority crystal structure of the target blank comprises a HCP structure, and a majority crystallographic orientation of the target blank comprises a {002} HCP plane that is substantially parallel to the target surface within a test region.

15. The target assembly of claim 14 wherein the target surface comprises a sputtering surface of the target assembly and the {002} HCP plane is substantially parallel to the sputtering surface across the entirety of the sputtering surface.

16. A diffusion bonded PVD target assembly comprising a target blank bonded to a backing plate, the target blank comprising a target surface and a magnetic material, a majority crystal structure of the target blank comprising a HCP structure, and a majority crystallographic orientation of the target blank comprising a {002} HCP plane that is substantially parallel to the target surface within a test region.

17. The target assembly of claim 16 wherein the target blank is bonded directly to a backing plate.

18. The target assembly of claim 16 wherein the test region defines a representative test region.

19. The target assembly of claim 16 wherein the target surface comprises a sputtering surface of the target assembly and the {002} HCP plane is substantially parallel to the sputtering surface across the entirety of the sputtering surface.

20. The target assembly of claim 16 wherein the target blank consists essentially of cobalt or a cobalt alloy with cobalt as the predominate metal.

21. The target assembly of claim 16 exhibiting a high PTF.

22. A PVD target fabrication method comprising:
diffusion bonding a target blank to a backing plate and forming a target assembly, a majority crystal structure of the target blank comprising a HCP structure;
transitioning at least some of the HCP structure to a non-HCP structure; and
restoring a majority of the non-HCP structure to the HCP structure.

23. The method of claim 22 wherein the target blank comprises a magnetic material.

24. The method of claim 22 wherein the target blank consists essentially of cobalt or a cobalt alloy with cobalt as the predominate metal.

25. The method of claim 22 wherein the backing plate consists essentially of aluminum, an aluminum alloy with aluminum as the predominate metal, copper, or a copper alloy with copper as the predominate metal.

26. The method of claim 22 wherein the transitioning comprises hot pressing the target blank and backing plate during the diffusion bonding at a temperature exceeding a HCP to non-HCP transition temperature of the target blank.

27. The method of claim 22 wherein the non-HCP structure comprises a FCC structure.

28. The method of claim 22 wherein the target blank exhibits a high PTF both before the diffusion bonding and after the restoring.

29. The method of claim 28 wherein the restoring comprises cooling the target blank from a diffusion bonding temperature to a room temperature of from about 10° C. to about 30° C. at a rate sufficient that the PTF after the restoring changes by greater than −10% in comparison to the PTF before the diffusion bonding.

30. The method of claim 22 wherein the target assembly lacks an interlayer between the target blank and the backing plate.

31. The method of claim 22 wherein the diffusion bond exhibits a bond strength of greater than about 11 ksi (76 MPa).

32. The method of claim 22 wherein the target assembly comprises a sputtering target assembly.

33. A PVD target fabrication method comprising:
diffusion bonding a target blank to a backing plate at a bonding temperature and forming a target assembly; and
cooling the target blank from the bonding temperature to a room temperature of from about 10° C. to about 30° C. at a rate sufficient that PTF of the diffusion bonded target blank changes by greater than −10% in comparison to the target blank PTF before the diffusion bonding.

34. The method of claim 33 wherein the cooling rate comprises less than or equal to about 5° C. per minute.

35. The method of claim 33 wherein the PTF changes by about 0%.

36. The method of claim 33 wherein the target blank consists essentially of cobalt or a cobalt alloy with cobalt as the predominate metal.

37. The method of claim 33 wherein the backing plate consists essentially of aluminum, an aluminum alloy with aluminum as the predominate metal, copper, or a copper alloy with copper as the predominate metal.

38. The method of claim 33 wherein the target blank exhibits a high PTF both before the diffusion bonding and after the cooling.

39. A PVD target fabrication method comprising:
diffusion bonding a cobalt-comprising target blank to an aluminum-comprising backing plate at a bonding temperature of greater than 412° C. and forming a target assembly, the target blank exhibiting a PTF of at least about 60% before the diffusion bonding; and
cooling the target blank from the bonding temperature to a room temperature of from about 10° C. to about 30° C. at a rate of no more than about 5° C. per minute, the diffusion bonded target assembly exhibiting a PTF of at least about 60% after the cooling.

40. The method of claim 39 wherein the target blank comprises a target surface, a majority crystal structure of the target blank comprises a HCP structure, and a majority crystallographic orientation of the target blank comprises a {002} HCP plane that is substantially parallel to the target surface within a test region.

41. A PVD target assembly produced by the method of claim 22.

42. A PVD target assembly produced by the method of claim 33.

43. A PVD target assembly produced by the method of claim 39.
